(19) United States
(12) Patent Application Publication
(10) Pub. No.: US 2013/0313019 A1
(43) Pub. Date: Nov. 28, 2013

(54) Casing for Network Transformers

(71) Applicant: Feei Cherng Enterprise Co., Ltd., New Taipei City (TW)

(72) Inventor: Kang-Xiang He, New Taipei City (TW)

(73) Assignee: FEEI CHERNG ENTERPRISE CO., LTD., New Taipei City (TW)

(21) Appl. No.: 13/958,731

(22) Filed: Aug. 5, 2013

Related U.S. Application Data
(62) Division of application No. 13/550,673, filed on Jul. 17, 2012.

(30) Foreign Application Priority Data
Oct. 13, 2011 (TW) 100219193

(51) Int. Cl. H05K 5/02

(52) U.S. Cl. CPC H05K 5/0247
USPC 174/541

(57) ABSTRACT

The invention provides a casing for network transformers. The casing includes a base, pins and a cover plate. The base has two side plates, two end plates and a bottom plate. The pins are embedded in the side plates of the base. Each of the pins has a first soldering portion formed by protruding from the bottom plate, a connecting portion formed by protruding from a surface of the side plate away from the bottom plate and a second soldering portion formed by extending from the connecting portion and then being bent, in which the first soldering portion extends to form a soldering segment, and the second soldering portion has a soldering surface. The first soldering portion fits to the bottom plate so as to increase its anti-deformation capability. The soldering surface is a larger flat surface so as to increase the soldering accuracy and convenience.

### CROSS-REFERENCE TO RELATED APPLICATIONS

The present application is a division of U.S. patent application Ser. No. 13/550,673 filed Jul. 17, 2012, which claims the priority benefit of Taiwan patent application serial no. 100219193, filed Oct. 13, 2011, the contents of which are hereby incorporated by reference herein in their entireties.

### BACKGROUND OF THE INVENTION

1. Field of the Invention

The invention relates to a casing for electronic elements and, more particularly, to a casing for network transformers such as local area network (LAN) transformers.

2. Description of the Prior Art

Referring to FIG. 1, there is shown a schematic diagram of a conventional casing 500 for network transformers. The casing 500 includes pins 510 which are spacedly embedded in two opposite side plates 530 of the casing 500. Each of the pins 510 has a soldering portion 511 and a bending portion 512, in which the soldering portion 511 is formed by protruding from a top surface 530a of the side plate 530 and then extending horizontally outward along the top surface 530a, and the bending portion 512 is formed by extending upward from the soldering portion 511 and then being bent outward. The casing 500 further includes protrusions 520 which are formed by protruding from the top surfaces 530a and interlaced with the pins 510. Ring coils 550 are disposed in a space 540 defined by the casing 500. Each leading wire 551 pulled from the ring coils 550 passes through a gap between the adjacent protrusions 520 and then is soldered to one of the soldering portions 511. In the process, the structure of the casing 500 needs the protrusions 520 to space the leading wires 551 apart to prevent them from short circuit, but the disposition of the protrusions 520 increases mold and material costs. The leading wires 551 passing through the protrusions 520 are clamped and fixed by a jig for positioning and then soldered to the soldering portions 511 by a spot soldering machine, but the bending portions 512 hinder the jig from fixing the leading wires 551 for positioning so as to increase process complexity.

Referring to FIG. 2, there is shown a schematic diagram of another conventional casing 600 for network transformers. The casing 600 includes pins 610 which are spacedly embedded in two opposite side plates 620 of the casing 600. Each of the pins 610 has a connecting portion 611 and a bending portion 612, in which the connecting portion 611 is formed by protruding from a top surface 620a of the side plate 620, and the bending portion 612 is formed by protruding from a side surface 620b of the side plate 620, extending upward and then being bent outward. Ring coils 640 are disposed in a space 630 defined by the casing 600. Each leading wire 641 pulled from the ring coils 640 is directly wound around one of the connecting portions 611 and then soldered to it by a spot soldering machine. The structure of the casing 600 does not need protrusions to space the leading wires 641 apart, but needs an additional process of winding the leading wires 641 around the connecting portions 611 and needs to adjust the spot soldering machine at a specific angle for soldering due to the nonflat surface of the connecting portions 611 so as to increase process complexity.

In addition, referring to FIGS. 1 and 2, distal ends 513 and 613 of the bending portions 512 and 612 of the pins 510 and 610 are for being soldered to pads on circuit boards (not shown) to fix the casings 500 and 600 on the circuit boards, respectively. In the consideration of design, the bending portions 512 and 612 need sufficient heights so as to decrease the structure strength of the pins 510 and 610 and easily cause the deformation of the pins 510 and 610 due to overexertion. And, because the openings of the spaces 540 and 630 face the circuit boards, the ring coils 550 and 640 improperly disposed in the spaces 540 and 630 may contact with the circuit boards when the casings 500 and 600 are fixed on the circuit boards. Accordingly, it may result that parts of the pins 510 and 610 are improperly soldered to the pads on the circuit boards to become unreliable joints.

### SUMMARY OF THE INVENTION

The invention is directed to providing a casing for network transformers for omitting the process of winding the leading wires around the pins, preventing the jig from being hindered from fixing the leading wires for positioning and solving the problem of the need for adjusting the spot soldering machine at a specific angle for soldering, so as to reduce process complexity.

The invention provides a casing for network transformers. The casing includes a base and pins. The base has a bottom plate. The bottom plate has a bottom plate first surface, a bottom plate second surface opposite to the bottom plate first surface, two opposite side edges and two opposite end edges. Two side plates are formed by extending in a direction perpendicular to the bottom plate first surface from the respective two side edges. Each of the two side plates has a side plate first surface and a side plate second surface adjacent to each other. The two side plate first surfaces of the two side plates face each other and are connected to the bottom plate first surface. The two side plate second surfaces of the two side plates are away from and parallel to the bottom plate first surface. Two end plates are formed by extending in the direction perpendicular to the bottom plate first surface from the respective two end edges. Each of the two end plates is connected to the two side plates and has an end plate first surface and an end plate second surface adjacent to each other. The two end plate first surfaces of the two end plates face each other and are connected to the bottom plate first surface. The two end plate second surfaces of the two end plates are away from and parallel to the bottom plate first surface. The two end plate first surfaces, the two side plate first surfaces and the bottom plate first surface define a space. The second soldering portion fits to the side plate second surface. The second soldering portion has a soldering surface which is away from the side plate second surface and parallel to the side plate second surface. The soldering surface is a flat surface whose area is greater than the sectional area of the connecting portion.

The pins are spacedly embedded in the two side plates and penetrate through the two side edges. Each of the pins has a first soldering portion, a connecting portion and a second soldering portion, in which the first soldering portion is formed by protruding from the bottom plate second surface, the connecting portion is formed by protruding from the side plate second surface and the second soldering portion is formed by extending from the connecting portion and then being bent toward the side plate second surface.

In one embodiment, the connecting portion is located at an edge or the center of the second soldering portion.

In one embodiment, the second soldering portions are formed by extending from the connecting portions located on both of the two side plates and then being bent inward or outward.

In one embodiment, the side plate first surface has spaced guide troughs. The guide troughs correspond in position to the second soldering portions or the soldering surfaces.

In one embodiment, the guide trough penetrates through the side plate second surface and has a guide trough inclined surface formed by the side plate first surface slanting toward the side plate second surface.

In one embodiment, a soldering segment is formed by extending along the bottom plate second surface from the first soldering portion and outward in a direction away from the side edge. The first soldering portion fits to the bottom plate second surface, and the soldering segment extends out of the bottom plate.

In one embodiment, the base further has a coupling recess disposed on an outer surface of the end plate. The casing further includes a cover plate. The cover plate has a coupling protrusion disposed on an end edge of the cover plate and corresponding to the coupling recess. The coupling protrusion is for being engaged with the coupling recess.

In one embodiment, the coupling recess has a first coupling portion, and the coupling protrusion has a second coupling portion corresponding to the first coupling portion. The coupling protrusion and the coupling recess are engaged with each other by the first coupling portion and the second coupling portion.

In one embodiment, the first coupling portion and the second coupling portion are two triangular, trapezoid or semicircular prisms corresponding to each other. In another embodiment, the first coupling portion is a semicircular protrusion and the second coupling portion is a semicircular recess corresponding to the first coupling portion. In another embodiment, the second coupling portion is a semicircular protrusion and the first coupling portion is a semicircular recess corresponding to the second coupling portion. In another embodiment, the first coupling portion is a step formed by part of the coupling recess being concaved inward and the second coupling portion is a right triangular prism. The right triangular prism is for being engaged with the step.

In one embodiment, the altitude of the end plate in a direction perpendicular to the bottom plate is greater than that of the side plate by a height difference, and the altitudes of the connecting portion and the second soldering portion in the direction perpendicular to the bottom plate are less than that of the end plate and within the height difference.

In one embodiment, the cover plate and the base are assembled together to have a unitary appearance.

In one embodiment, the side plate second surface and the end plate second surface are connected to form a flat surface. In another embodiment, the side plate second surface and the end plate second surface are connected to form a non-flat surface having a height difference.

In one embodiment, ring coils are disposed in the space. Leading wires pulled from the ring coils are soldered to the second soldering portions, respectively.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a schematic diagram of a conventional casing for network transformers;

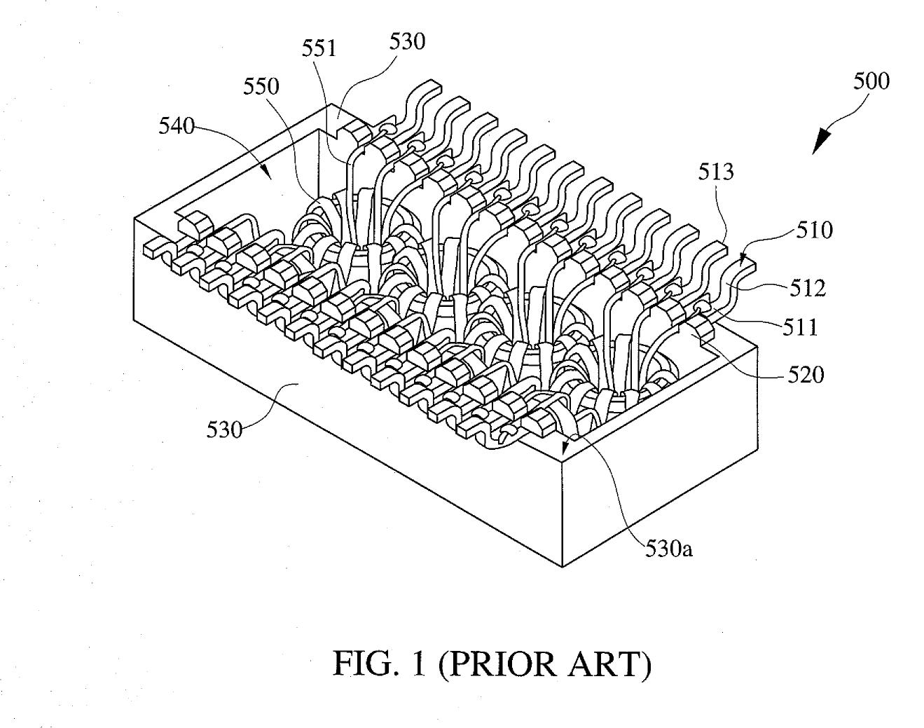

FIG. 2 shows a schematic diagram of another conventional casing for network transformers;

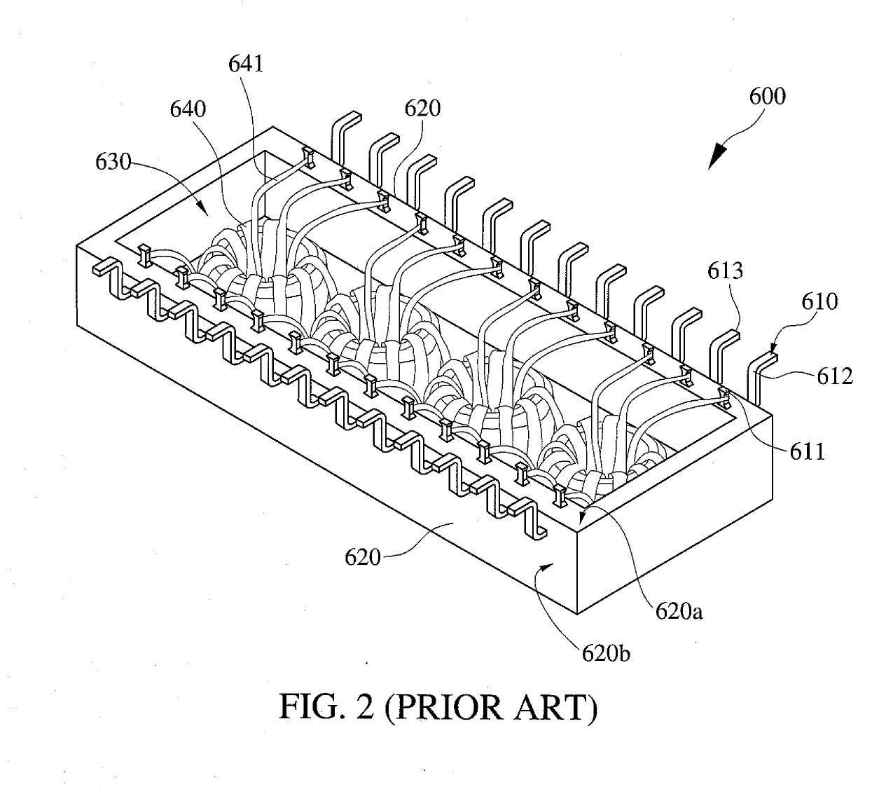

FIG. 3 shows a partially exploded perspective view of a casing for network transformers according to a preferred embodiment of the invention;

FIG. 4 shows a sectional side view of the casing as shown in FIG. 3;

FIG. 5 shows a perspective view of network transformers disposed in the casing as shown in FIG. 3; and

FIG. 6 shows an assembled perspective view of the casing as shown in FIG. 3.

### DESCRIPTION OF THE PREFERRED EMBODIMENTS

Reference will now be made in detail to the preferred embodiments of the invention, examples of which are illustrated in the accompanying drawings. Wherever possible, the same reference numbers are used in the drawings and the description to refer to the same or like parts.

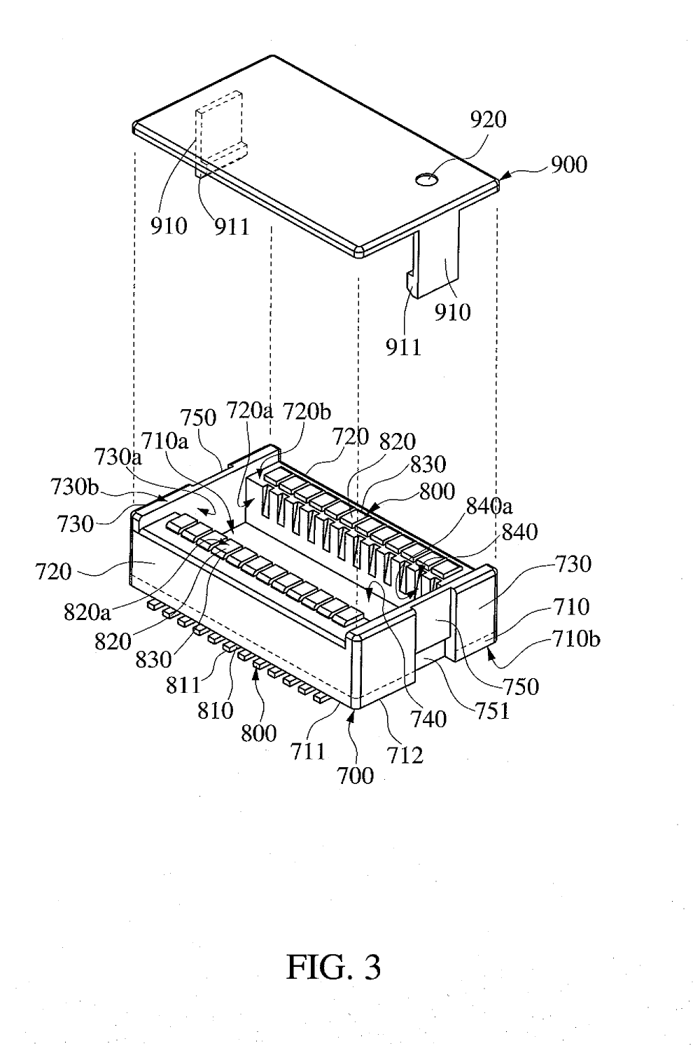

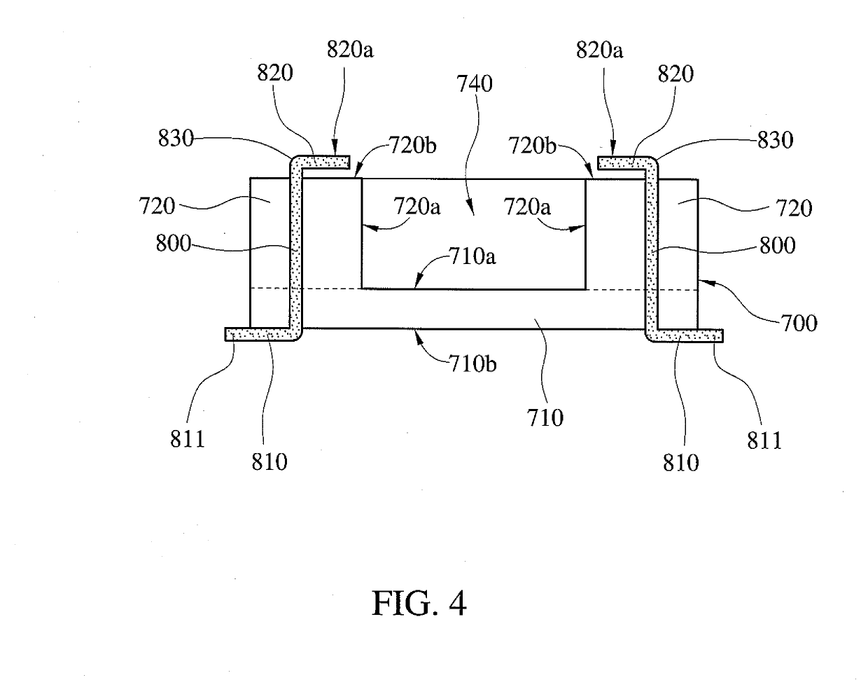

Referring to FIGS. 3 and 4, there are shown a partially exploded perspective view and a sectional side view of a casing for network transformers according to a preferred embodiment of the invention respectively. The casing includes a base 700, pins 800 and a cover plate 900. The base 700 has a bottom plate 710. The bottom plate 710 may have a through hole (not shown) disposed therethrough for positioning. The bottom plate 710 has a bottom plate first surface 710a and a bottom plate second surface 710b opposite to each other. The bottom plate 710 further has two opposite side edges 711 and two opposite end edges 712.

Two side plates 720 are formed by extending in a direction perpendicular to the bottom plate first surface 710a from the respective two side edges 711. Each of the two side plates 720 has a side plate first surface 720a and a side plate second surface 720b adjacent to each other. The two side plate first surfaces 720a of the two side plates 720 face each other and are connected to the bottom plate first surface 710a. The two side plate second surfaces 720b of the two side plates 720 are away from and parallel to the bottom plate first surface 710a. Two end plates 730 are formed by extending in the direction perpendicular to the bottom plate first surface 710a from the respective two end edges 712. Each of the two end plates 730 is connected to the two side plates 720 and has an end plate first surface 730a and an end plate second surface 730b adjacent to each other. The two end plate first surfaces 730a of the two end plates 730 face each other and are connected to the bottom plate first surface 710a. The two end plate second surfaces 730b of the two end plates 730 are away from and parallel to the bottom plate first surface 710a.

The two end plate first surfaces 730a, the two side plate first surfaces 720a and the bottom plate first surface 710a define a space 740 of the base 700. The two side plates 720 and the two end plates 730 and the bottom plate 710 may be formed integrally.

The pins 800 are spacedly embedded in the two side plates 720 and penetrate through the two side edges 711 of the bottom plate 710. More specifically speaking, the pins 800 penetrate through connection parts of the bottom plate 710 and the two side plate 720. Furthermore, each of the pins 800 has a first soldering portion 810 formed by protruding from the bottom plate second surface 710b. The first soldering portion 810 has a soldering segment 811 formed by extending along the bottom plate second surface 710b from the first soldering portion 810 and outward in a direction away from the side edge 711 of the bottom plate 710. As shown in FIG. 4, the first soldering portions 810 located on left side of the base 700 extend leftward, and the first soldering portions 810 located on right side of the base 700 extend rightward. The soldering segments 811 extend out of the bottom plate 710 so that a spot soldering machine may solder the soldering segments 811 to pads on a circuit board (not shown).

In the embodiment, the first soldering portions 810 fit to the bottom plate second surface 710b so as to increase the structure strength of the pins 800. When an external force is applied to the casing, the first soldering portions 810 are supported by the bottom plate second surface 710b against the effect of the applied external force, and hence the first soldering portions 810 are not easy to cause deformation. It prevents the soldering segment 811 from being improperly soldered to the pads on the circuit board due to the deformation of the first soldering portions 810.

The pins 800 further penetrate through the two side plate second surface 720b. Furthermore, each of the pins 800 further has a connecting portion 830 and a second soldering portion 820, in which the connecting portion 830 is formed by protruding from the side plate second surface 720b, and the second soldering portion 820 is formed by extending from the connecting portion 830 and then being bent toward the side plate second surface 720b. In the embodiment, the second soldering portions 820 are formed by extending from the connecting portions 830 located on both of the two side plates 720 and then being bent inward, and each of the connecting portions 830 is located at an edge of the corresponding second soldering portion 820. As shown in FIG. 4, the left second soldering portions 820 are formed by extending from the connecting portions 830 located on the left side plate 720 and then being bent rightward, and the right second soldering portions 820 are formed by extending from the connecting portions 830 located on the right side plate 720 and then being bent leftward, but which is not intended to limit the scope of the invention. In another embodiment, the second soldering portions may be formed by extending from the connecting portions located on both of the two side plates but then being bent outward, and each of the second soldering portions may be formed by uniformly extending from the corresponding connecting portion; that is, each of the connecting portions may be located at the center of the corresponding second soldering portion. In addition, the second soldering portions 820 may fit to the side plate second surface 720b of the side plate 720.

Each of the second soldering portions 820 has a soldering surface 820a away from the side plate second surface 720b. The soldering surface 820a is a flat surface, and the area of the soldering surface 820a is greater than the sectional area of the corresponding connecting portion 830. The soldering surface 820a is substantially parallel to the side plate second surface 720b. In the invention, the soldering surfaces 820a are designed to be larger, flat and substantially parallel to the side plate second surface 720b so as to increase the soldering accuracy and convenience. Each of the side plate first surface 720a has a plurality of spaced guide troughs 840. In the embodiment, the guide troughs 840 correspond in position to the soldering surfaces 820a, but which is not intended to limit the scope of the invention. In another embodiment, the guide troughs may correspond in position to the second soldering portions. Each of the guide troughs 840 penetrates through the side plate second surface 720b and has a guide trough inclined surface 840a formed by the side plate first surface 720a slanting toward the side plate second surface 720b.

In the embodiment, the side plate second surface 720b and the end plate second surface 730b are connected to form a non-flat surface having a height difference. In other words, the end plate 730 is higher than the side plate 720. More specifically speaking, the altitude of the end plate 730 in a direction perpendicular to the bottom plate 710 is greater than that of the side plate 720 by the height difference. The altitudes of the connecting portion 830 and the second soldering portion 820 in the direction perpendicular to the bottom plate 710 are less than that of the end plate 730; that is, the altitudes of the connecting portion 830 and the second soldering portion 820 are within the height difference. The end plate 730 has an outer surface having a coupling recess 750 disposed thereon, and the coupling recess 750 has a first coupling portion 751 which is a step formed by part of the coupling recess 750 being concaved inward.

The cover plate 900 has two end edges and each of the two end edges has a coupling protrusion 910 formed by extending downward therefrom and corresponding to the coupling recess 750. The coupling protrusion 910 has a second coupling portion 911 corresponding to the first coupling portion 751. When the second coupling portion 911 and the first coupling portion 751 are engaged with each other by the right triangular prism being engaged with the step and the coupling protrusion 910 being engaged with the coupling recess 750, the cover plate 900 and the base 700 are assembled together to have a unitary appearance. In addition, the cover plate 900 further has a through hole 920 disposed therethrough for positioning. When the cover plate 900 and the base 700 are assembled, the through hole 320 corresponds in position to the through hole (not shown) disposed through the bottom plate 710.

In the embodiment, the coupling protrusion 910 and the coupling recess 750 are engaged with each other by the first coupling portion 751 and the second coupling portion 911, and the first coupling portion 751 and the second coupling portion 911 are two right triangular prisms corresponding to each other. In one embodiment, the first coupling portion and the second coupling portion may be two triangular, trapezoid or semicircular prisms corresponding to each other. In another embodiment, the first coupling portion may be a semicircular protrusion, and the second coupling portion may be a semicircular recess corresponding to the first coupling portion. In another embodiment, the second coupling portion may be a semicircular protrusion, and the first coupling portion may be a semicircular recess corresponding to the second coupling portion.

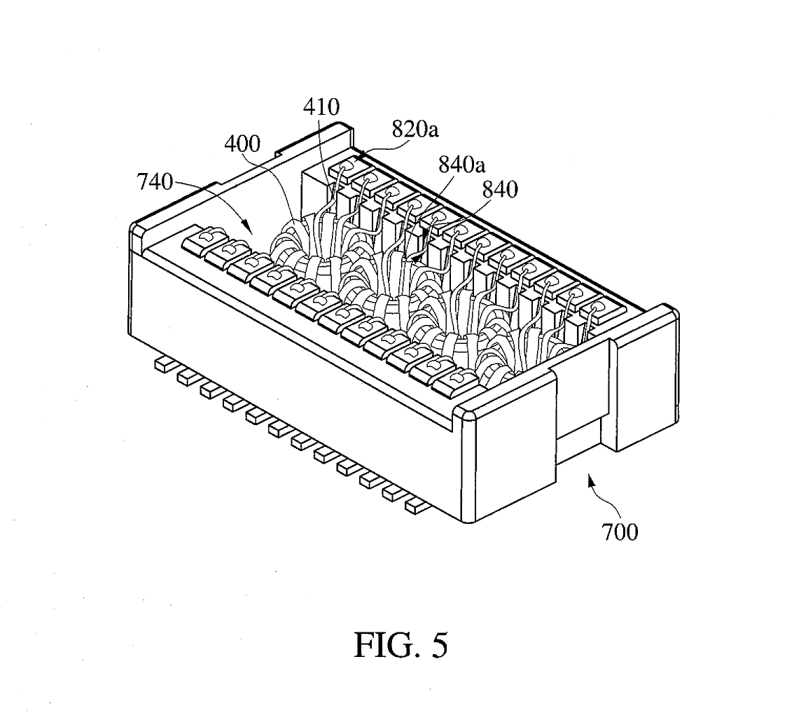

Referring to FIG. 5, there is shown a perspective view of network transformers disposed in the casing as shown in FIG. 3. Ring coils 400 are disposed in the space 740 defined by the base 700. In the process, leading wires 410 pulled from the ring coils 400 pass through the guide troughs 840 from the guide trough inclined surfaces 840a up to the soldering surfaces 820a, respectively. Next, the leading wires 410 passing through the soldering surfaces 820a are clamped and fixed by a jig for positioning. Finally, the leading wires 410 are soldered to the soldering surfaces 820a, respectively, by the spot soldering machine and then excess wires are cut off.

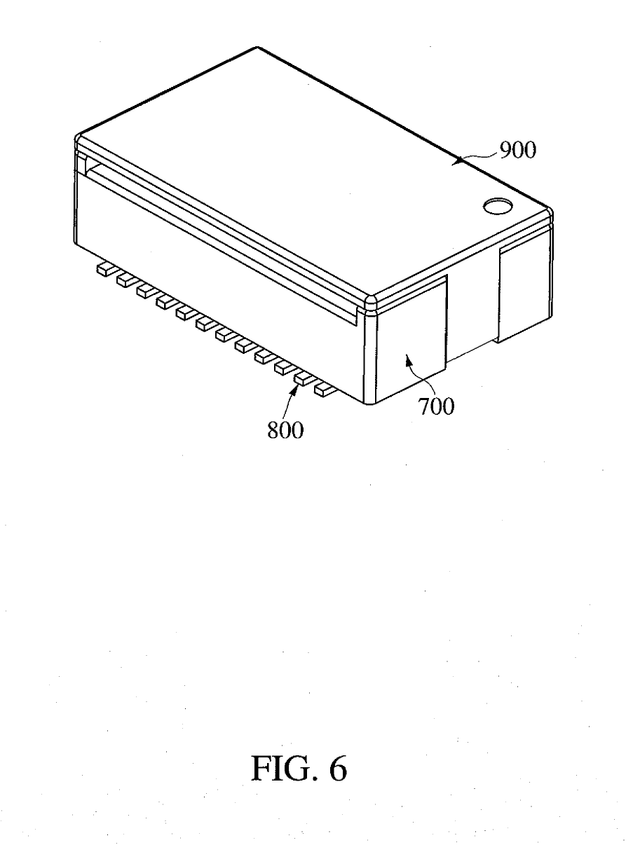

Referring to FIG. 6, there is shown an assembled perspective view of the casing as shown in FIG. 3. After the ring coils 400 are disposed in the space 740 defined by the base 700, and the leading wires 410 pulled from the ring coils 400 are soldered to the soldering surfaces 820a, respectively, and then the excess wires are cut off, the second coupling portion 911 and the first coupling portion 751 are engaged with each other by the right triangular prism being engaged with the step and the coupling protrusion 910 being engaged with the coupling recess 750 so that the cover plate 900 and the base 700 are assembled together to have a unitary appearance.

In summary, the casing of the invention has several advantages over prior art. First, the cover plate and the base are assembled together to have a unitary appearance by the coupling protrusions being engaged with the coupling recess. Second, when the leading wires are clamped and fixed by the jig for positioning, the soldering surfaces do not hinder the jig from fixing the leading wires for positioning so as to increase positioning convenience and accuracy. Third, compared to the connecting portions, the soldering surfaces are designed to be larger and flat so as to increase the soldering accuracy and convenience and reduce the material cost of the pins. Fourth, the first soldering portions are designed to fit to the bottom plate and only the soldering segments extend out of the bottom plate so that the pins have better structure strength and are not easy to cause deformation. Fifth, the opening of the space faces upward instead of facing the circuit board so that it prevents the ring coils improperly disposed in the space from contacting with the circuit board to result in unreliable joints when the casing is fixed on the circuit board.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

I claim:

1. A casing for network transformers, comprising:
a base having a bottom plate having a bottom plate first surface, a bottom plate second surface opposite to the bottom plate first surface, two opposite side edges and two opposite end edges, two side plates being formed by extending in a direction perpendicular to the bottom plate first surface from the respective two side edges, each of the two side plates having a side plate first surface and a side plate second surface adjacent to each other, the two side plate first surfaces facing each other and being connected to the bottom plate first surface, the two side plate second surfaces being away from and parallel to the bottom plate first surface, two end plates being formed by extending in the direction perpendicular to the bottom plate first surface from the respective two end edges, each of the two end plates being connected to the two side plates and having an end plate first surface and an end plate second surface adjacent to each other, the two end plate first surfaces facing each other and being connected to the bottom plate first surface, the two end plate second surfaces being away from and parallel to the bottom plate first surface, the two end plate first surfaces, the two side plate first surfaces and the bottom plate first surface defining a space; and
a plurality of pins being spacedly embedded in the two side plates and penetrating through the two side edges, each of the pins has a first soldering portion formed by protruding from the bottom plate second surface, a connecting portion formed by protruding from the side plate second surface and a second soldering portion formed by extending from the connecting portion and then being bent toward the side plate second surface, the second soldering portion fitting to the side plate second surface, the second soldering portion having a soldering surface away from and parallel to the side plate second surface, the soldering surface being a flat surface whose area is greater than the sectional area of the connecting portion.

2. The casing as claimed in claim 1, wherein the connecting portion is located at an edge of the second soldering portion.

3. The casing as claimed in claim 2, wherein the second soldering portions are formed by extending from the connecting portions located on both of the two side plates and then being bent inward or outward.

4. The casing as claimed in claim 1, wherein the connecting portion is located at the center of the second soldering portion.

5. The casing as claimed in claim 1, wherein the side plate first surface has a plurality of spaced guide troughs, and the guide troughs correspond in position to the second soldering portions or the soldering surfaces.

6. The casing as claimed in claim 5, wherein the guide trough penetrates through the side plate second surface and has a guide trough inclined surface formed by the side plate first surface slanting toward the side plate second surface.

7. The casing as claimed in claim 1, wherein a soldering segment is formed by extending along the bottom plate second surface from the first soldering portion and outward in a direction away from the side edge.

8. The casing as claimed in claim 7, wherein the first soldering portion fits to the bottom plate second surface, and the soldering segment extends out of the bottom plate.

9. The casing as claimed in claim 1, wherein the base further has a coupling recess disposed on an outer surface of the end plate, and the casing further comprises a cover plate having a coupling protrusion disposed on an end edge of the cover plate and corresponding to the coupling recess, the coupling protrusion being engaged with the coupling recess.

10. The casing as claimed in claim 9, wherein the coupling recess has a first coupling portion, and the coupling protrusion has a second coupling portion corresponding to the first coupling portion, the coupling protrusion and the coupling recess being engaged with each other by the first coupling portion and the second coupling portion.

11. The casing as claimed in claim 10, wherein the first coupling portion and the second coupling portion are two triangular, trapezoid or semicircular prisms corresponding to each other; or the first coupling portion is a semicircular protrusion and the second coupling portion is a semicircular recess corresponding to the first coupling portion; or the second coupling portion is a semicircular protrusion and the first coupling portion is a semicircular recess corresponding to the second coupling portion; or the first coupling portion is a step formed by part of the coupling recess being concaved inward and the second coupling portion is a right triangular prism, the right triangular prism being engaged with the step.

12. The casing as claimed in claim 9, wherein the altitude of the end plate in a direction perpendicular to the bottom plate is greater than that of the side plate by a height difference, and the altitudes of the connecting portion and the second soldering portion in the direction perpendicular to the bottom plate are less than that of the end plate and within the height difference.

13. The casing as claimed in claim 9, wherein the cover plate and the base are assembled together to have a unitary appearance.

14. The casing as claimed in claim 1, wherein the side plate second surface and the end plate second surface are connected to form a flat surface; or the side plate second surface and the end plate second surface are connected to form a non-flat surface having a height difference.

15. The casing as claimed in claim I, wherein a plurality of ring coils are disposed in the space, and a plurality of leading wires pulled from the ring coils are soldered to the second soldering portions, respectively.
